(19) United States
(12) Patent Application Publication
(10) Pub. No.: US 2025/0256373 A1
(43) Pub. Date: Aug. 14, 2025

(54) Generation of Starting Thickness Profile Using In-SITU Monitoring System

(71) Applicant: Applied Materials, Inc., Santa Clara, CA (US)

(72) Inventors: Kun XU, Sunol, CA (US); Benjamin CHERIAN, San Jose, CA (US); Harry Q. LEE, Los Altos, CA (US); Yongneng WU, Santa Clara, CA (US); Heejun CHOI, Santa Clara, CA (US); Jun QIAN, Sunnyvale, CA (US); Yixin YING, Santa Clara, CA (US); David Maxwell GAGE, Sunnyvale, CA (US)

(21) Appl. No.: 18/440,490

(22) Filed: Feb. 13, 2024

(51) Int. Cl. B24B 49/04; B24B 49/10; H01L 21/66

(52) U.S. Cl. CPC B24B 49/04; B24B 49/10; H01L 22/12

(57) ABSTRACT

A method of determining a starting thickness profile for a conductive layer on a substrate includes monitoring a calibration substrate during polishing to generate a sequence of first traces, detecting exposure of an underlying layer, and continuing to monitor the calibration substrate after exposure to generate a second trace. The second trace is subtracted from each first trace to generate a sequence of modified traces. For each zone on the substrate, a portion of the modified first trace corresponding to the zone is converted into a thickness value for the zone, thereby providing a plurality of sequences of thickness values. For each respective zone a function is fit to the sequence of thickness values for the respective zone thereby providing a plurality of fit functions, and a starting thickness profile for the conductive layer at a start of polishing using the plurality of fit functions.

### TECHNICAL FIELD

The present disclosure relates to chemical mechanical polishing, and more specifically to monitoring of a conductive layer during chemical mechanical polishing.

### BACKGROUND

An integrated circuit is typically formed on a substrate by the sequential deposition of conductive, semiconductive, or insulative layers on a silicon wafer. A variety of fabrication processes require planarization of a layer on the substrate. For example, one fabrication step involves depositing a filler layer over a non-planar surface and planarizing the filler layer. For certain applications, the filler layer is planarized until the top surface of a patterned layer is exposed. For example, a metal layer can be deposited on a patterned insulative layer to fill the trenches and holes in the insulative layer. After planarization, the remaining portions of the metal in the trenches and holes of the patterned layer form vias, plugs, and lines to provide conductive paths between thin film circuits on the substrate.

Chemical mechanical polishing (CMP) is one accepted method of planarization. This planarization method typically requires that the substrate be mounted on a carrier head. The exposed surface of the substrate is typically placed against a rotating polishing pad. The carrier head provides a controllable load on the substrate to push it against the polishing pad. Polishing slurry with abrasive particles is typically supplied to the surface of the polishing pad.

One problem in CMP is determining whether the polishing process is complete, i.e., whether a substrate layer has been planarized to a desired flatness or thickness, or when a desired amount of material has been removed. Variations in the slurry composition, the polishing pad condition, the relative speed between the polishing pad and the substrate, the initial thickness of the substrate layer, and the load on the substrate can cause variations in the material removal rate. These variations cause variations in the time needed to reach the polishing endpoint. Therefore, determining the polishing endpoint merely as a function of polishing time can lead to non-uniformity within a wafer or from wafer to wafer.

In some systems, a substrate is monitored in-situ during polishing, e.g., through the polishing pad. One monitoring technique is to induce an eddy current in the conductive layer and detect the change in the eddy current as the conductive layer is removed.

### SUMMARY

In one aspect, a starting thickness value of a conductive outer layer in a zone on a substrate is received, and an initial target thickness value for the conductive outer layer in the zone on the substrate is received. The starting thickness value is generated prior to polishing and representing a thickness of the outer layer in the zone prior to polishing, and the initial target thickness profile is generated prior to polishing and represents a desired thickness for the outer layer in the zone after polishing. The conductive outer layer on the substrate is polished, and the substrate is monitored during polishing with an in-situ monitoring system so as to generate a sequence of signal values that depend on a thickness of the conductive outer layer and on thickness and/or conductivity of one or more underlying layers below the outer layer. The sequence of signal values from the zone is converted into a sequence of effective thickness values for the zone with each effective thickness value including contributions of the outer layer and the one or more underlying layers. A function is fit to the sequence of effective thickness values, an effective starting thickness value for the layer at a start of polishing is determined using the fitted function, and an adjusted target thickness value is calculated based on the initial target value, the effective starting thickness value, and the starting thickness value. A polishing endpoint is detected or a polishing parameter is modified based on the sequences of effective thickness values and the adjusted target thickness value.

In another aspect, prior to polishing, a starting thickness profile is received for a conductive outer layer on a substrate and an initial target thickness profile is received for the conductive outer layer on the substrate. The starting thickness profile representing a thickness of the outer layer at a plurality of zones on the substrate prior to polishing, and the initial target thickness profile representing a desired thickness for the outer layer at the plurality of zones after polishing. During polishing of the substrate a sequence of signal values that depend on a thickness of the conductive outer layer being polished and on thickness and/or conductivity of one or more underlying layers below the outer layer is received from an in-situ monitoring system. For each respective zone of the plurality of zones, the sequence of signal values from the respective zone is converted into a sequence of effective thickness values for the respective zone with each effective thickness value including contributions of the conductive outer layer and the one or more underlying layers, thereby providing a plurality of sequences of effective thickness values with each respective sequence of the plurality of sequences corresponding to a respective zone. For each respective zone of the plurality of zones, function is fit to the sequence of effective thickness values, thereby providing a plurality of fit functions with each respective fit function of the plurality of fit functions corresponding to a respective zone. An effective starting thickness profile is determined for the layer at a start of polishing using the plurality of fit functions, and an adjusted target thickness profile is calculated based on the initial target thickness profile, the effective starting thickness profile, and the starting thickness profile. A polishing parameter is modified based on the plurality of sequences of effective thickness values and the adjusted target thickness profile.

In another aspect, a method of determining a starting thickness profile for a layer on a substrate includes polishing a conductive outer layer on a calibration substrate, monitoring the calibration substrate during the polishing by repeatedly sweeping a sensor of an in-situ monitoring system across the calibration substrate so as to generate a sequence of first traces with each first trace of the sequence of first traces corresponding to a sweep by the sensor and each first trace including a sequence of effective thickness values that depend on a thickness of the conductive outer layer and on thickness and/or conductivity of one or more underlying layers below the outer layer, detecting exposure of the one or more underlying layers below the outer layer, following exposure of the one or more underlying layers continuing to monitor the calibration substrate by sweeping the sensor of the in-situ monitoring system across the calibration substrate and generating a second trace that includes a sequence of underlying thickness values that depend on the thickness and/or conductivity of the one or more underlying layers, for each respective first trace from the sequence of first traces subtracting the second trace from the first trace to generate a modified first trace thereby generating a sequence of modified traces, for each respective zone of a plurality of zones on the substrate and each respective modified trace from the sequence of modified traces converting a portion of the sequence of signal values from the respective zone for the respective modified trace into a thickness value for the respective zone thereby providing a plurality of sequences of thickness values with each respective sequence of the plurality of sequences corresponding to a respective zone, for each respective zone of the plurality of zones fitting a function to the sequence of thickness values for the respective zone thereby providing a plurality of fit functions with each respective fit function of the plurality of fit functions corresponding to a respective zone, and determining a starting thickness profile for the conductive layer at a start of polishing using the plurality of fit functions.

Implementations of the methods, the computer program products, and/or the systems to carry out this aspect may include one or more of the following features.

Calculating the adjusted target thickness value may include calculating an adjustment based on a difference between the starting thickness value and the initial target value. Calculating the adjusted target thickness value may include subtracting the adjustment from the effective starting thickness value. Calculating the adjustment includes multiplying the difference between the starting thickness value and the initial target value by a constant. The constant may be between 1.0 and 1.2.

The function may be a linear function. Determining the effective starting thickness value may include extrapolating the function backward to a starting time for the polishing. The in-situ monitoring system may be an eddy current monitoring system. The polishing endpoint may be detected by determining a time at which the function equals the adjusted target thickness value. Fitting the function may include repeatedly fitting the function to a running window of effective thickness values from the sequence of effective thickness values.

Converting the sequence of signal values from the zone into the sequence of effective thickness values may include calculating a sequence of preliminary effective thickness values from the effective thickness values using a conversion algorithm that accepts a signal value as an input and generates a thickness value as an output. A sensor of the in-situ monitoring system may perform a plurality of sweeps across the substrate to generate a sequence of traces, and each respective trace of the sequence of traces may be defined by thickness values from the sequence of thickness values for a respective sweep of the plurality of sweeps. For each respective trace, edge reconstruction may be performed on the respective trace to generate a modified trace having modified thickness values, thereby generating a sequence of modified traces. For each respective trace, an effective thickness value may be calculated for the zone from the modified thickness values from the zone for the respective trace, thereby generating the sequence of effective thickness values. Calculating the effective thickness value for the zone from the modified thickness values may include averaging modified thickness values from the zone.

Implementations may include one or more of the following advantages. In calculation of the thickness of the layer being polished based on a monitored signal, the technique can compensate for contributions to the signal by conductive underlayers, e.g., a doped substrate or metal layers, even when the underlayer contribution is inconsistent on a wafer-to-wafer basis. Thus, the thickness of the layer being polished can be calculated with higher accuracy or reliability. The calculated thickness can be used for determining control parameters during a polishing process and/or determining an endpoint for the polishing process. Reliability of the control parameter determination and endpoint detection can be improved, wafer under-polish can be avoided, and wafer-to-wafer non-uniformity (WTWNU) and within-wafer non-uniformity (WIWNU) can be reduced.

The details of one or more implementations are set forth in the accompanying drawings and the description below. Other aspects, features, and advantages will be apparent from the description and drawings, and from the claims.

### BRIEF DESCRIPTION OF THE DRAWINGS

FIG. 1 illustrates a schematic cross-sectional view of an example of a polishing station including an electromagnetic induction monitoring system.

FIG. 2 illustrates a schematic top view of an example chemical mechanical polishing station showing a path of a sensor scan across a substrate.

FIGS. 3A-3C are schematic cross-sectional views of a substrate illustrating a polishing process.

FIG. 4 is a schematic cross-sectional view illustrating an example magnetic field generated by an electromagnetic induction sensor.

FIG. 5 illustrates a graph of an example signal from an eddy current sensor as a function of conductive layer thickness.

FIG. 6 illustrates a flow chart of a method for performing endpoint and profile control in chemical mechanical polishing.

FIG. 7 is a graph of a sequence of thickness values.

FIG. 8 is a graph of two sequences of thickness values from two different radial ranges on a production substrate.

FIGS. 9A-9C illustrate a flow chart of another implementation of a method for performing endpoint and profile control in chemical mechanical polishing.

FIG. 10 is a graph of two sequences of effective thickness values from two different radial ranges during polishing of a calibration substrate.

FIG. 11 is a graph of two sequences of thickness values from two different radial ranges derived from polishing of the calibration substrate.

FIG. 12 is a graph of an effective thickness trace from polishing of a calibration substrate.

FIG. 13 is a graph of an effective thickness trace from over-polishing of the calibration substrate.

FIG. 14 is a graph of a thickness trace derived from the traces of FIGS. 12 and 13.

FIG. 15 is a graph of an effective thickness trace from polishing of a production substrate.

### DETAILED DESCRIPTION

One monitoring technique for a polishing operation is to induce eddy currents in a conductive layer on a substrate, e.g., using an alternating current (AC) drive signal. The induced eddy currents can be measured by an eddy current sensor in-situ during polishing to generate a signal. Assuming the outermost layer undergoing polishing is a conductive layer, then the signal from the sensor should be dependent on the thickness of the conductive layer. Based on the monitoring, control parameters for the polishing operation, such as polishing rate, can be adjusted in-situ. In addition, the polishing operation can terminate based on an indication that the monitored thickness has reached a desired endpoint thickness.

In practice, the magnetic field generated by the eddy current sensor does not stop within the outermost conductive layer, but can extend into underlying conductive layers or the underlying substrate. As a result, the signal generated by the eddy current sensor can depend on the conductivity of the semiconductor wafer and the presence of the underlying conductive layers. If the semiconductor wafer is not doped, e.g., as typically used in “blank” wafers used for system calibration and basic substrate wafers, the electrical resistance of the wafer can be sufficiently high that the presence of the wafer does not have detectable influence on the eddy current signal. However, for actual device fabrication the wafers will typically be doped, e.g., highly doped, for various purposes. In this situation, the signal generated by the eddy current sensor can have significant contribution from the substrate, depending on the conductivity of the semiconductor wafer. As such, thickness measurement based on signals captured by the eddy current sensor can be inaccurate.

If the contribution of the substrate due to doping is known, then calculation of the thickness of the layer being polished can take into account the contribution to the signal from the semiconductor substrate. However, often doping is poorly controlled during semiconductor device fabrication, both across a given wafer and on a wafer-to-wafer basis within a given production lot.

The present disclosure concerns a technique to perform endpoint and profile control when the underlayer, e.g., the doped semiconductor wafer, has an inconsistent contribution to the signal from the eddy current sensor. A starting effective thickness profile can be calculated by calculating a polishing rate for each of a plurality of zones on the substrate based on the signals from the sensor and extrapolating the effective thickness backwards to the start of the polishing operation for each zone. Then a deposited layer profile representing the actual starting thickness of the deposited film can be subtracted from the effective starting thickness profile to provide an underlayer profile, i.e., a contribution of the underlayers in the form of an effective thickness. The underlying profile can then be added to a target thickness profile to generate an adjusted target thickness profile, and this adjusted target thickness profile can be used for endpoint detection.

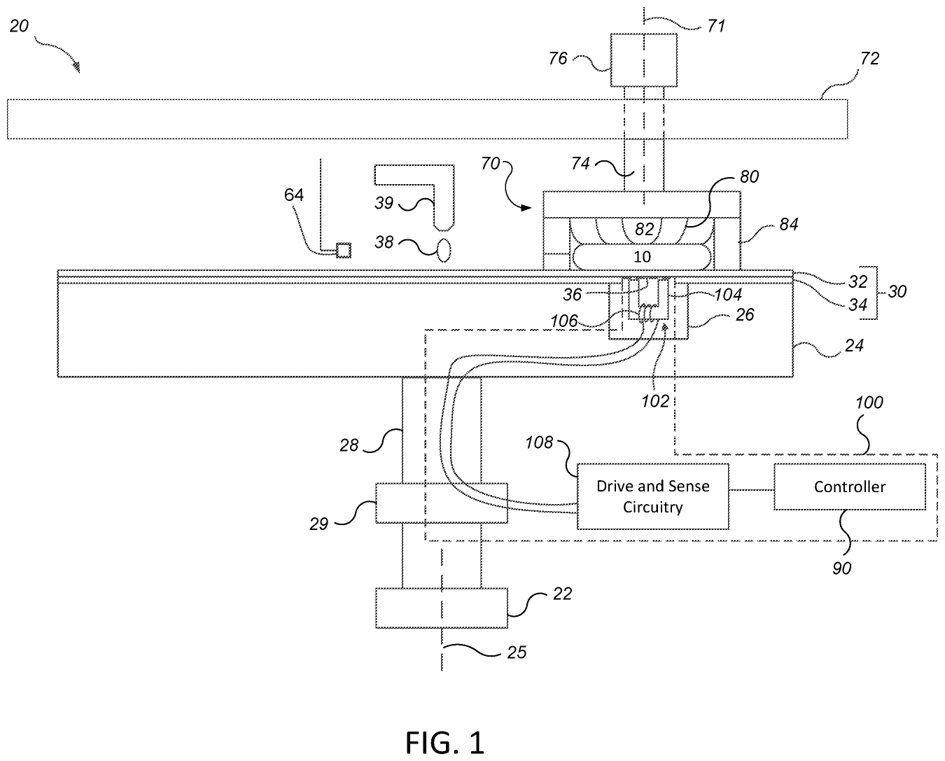

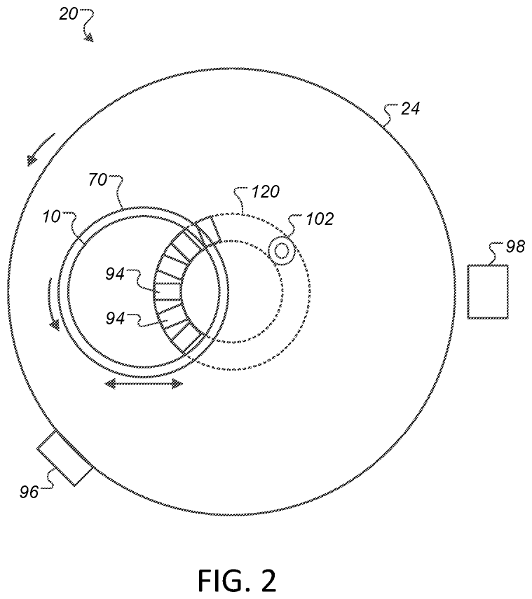

FIGS. 1 and 2 illustrate an example of a polishing station 20 of a chemical mechanical polishing system. The polishing station 20 includes a rotatable disk-shaped platen 24 on which a polishing pad 30 is situated. The platen 24 is operable to rotate about an axis 25. For example, a motor 22 can turn a drive shaft 28 to rotate the platen 24. The polishing pad 30 can be a two-layer polishing pad with an outer polishing layer 34 and a softer backing layer 32.

The polishing station 20 can include a supply port or a combined supply-rinse arm 39 to dispense a polishing liquid 38, such as an abrasive slurry, onto the polishing pad 30. The polishing station 20 can include a pad conditioner apparatus with a conditioning disk to maintain the surface roughness of the polishing pad.

A carrier head 70 is operable to hold a substrate 10 against the polishing pad 30. The carrier head 70 is suspended from a support structure 72, e.g., a carousel or a track, and is connected by a drive shaft 74 to a carrier head rotation motor 76 so that the carrier head can rotate about an axis 71. Optionally, the carrier head 70 can oscillate laterally, e.g., on sliders on the carousel, by movement along the track, or by rotational oscillation of the carousel itself.

The carrier head 70 can include a flexible membrane 80 having a substrate mounting surface to contact the back side of the substrate 10. The membrane 80 can form a plurality of pressurizable chambers 82 to apply different pressures to different zones, e.g., different radial zones, on the substrate 10. The carrier head can also include a retaining ring 84 to hold the substrate below the membrane 80.

In operation, the platen is rotated about its central axis 25, and the carrier head is rotated about its central axis 71 and translated laterally across the top surface of the polishing pad 30. Where there are multiple carrier heads, each carrier head 70 can have independent control of its polishing parameters, for example each carrier head can independently control the pressure applied to each respective substrate.

In some implementations, the polishing station 20 includes a temperature sensor 64 to monitor a temperature in the polishing station or a component of/in the polishing station.

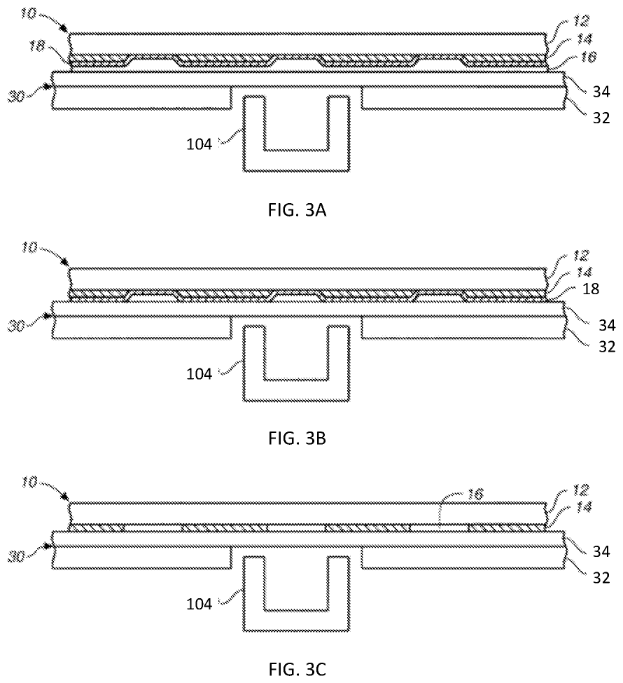

Referring to FIG. 3A, the polishing system can be used to polish a substrate 10 that includes a conductive material overlying and/or inlaid in a patterned dielectric layer. For example, the substrate 10 can include a layer of conductive material 16, e.g., a metal, e.g., copper, aluminum, cobalt or titanium, that overlies and fills trenches in a dielectric layer 14, e.g., silicon oxide or a high-k dielectric. Optionally a barrier layer 18, e.g., tantalum or tantalum nitride, can line the trenches and separate the conductive material 16 from the dielectric layer 14. The conductive material 16 in the trenches can provide vias, pads and/or interconnects in a completed integrated circuit. Although the dielectric layer 14 is illustrated as deposited directly on a semiconductor wafer 12, one or more other layers can be interposed between the dielectric layer 14 and the wafer 12.

The semiconductor wafer 12 can be a silicon wafer, e.g., single crystalline silicon, although other semiconductor materials are possible, e.g., gallium arsenide or gallium nitride. In addition, the semiconductor wafer 12 can be doped, e.g., with p-type or n-type doping. The doping can be uniform laterally across the wafer, or the wafer can be selectively doped, e.g., as appropriate for fabrication of transistors in integrated circuits using the semiconductor wafer.

Initially, the conductive material 16 overlies the entire dielectric layer 14. As polishing progresses, the bulk of the conductive material 16 is removed, exposing the barrier layer 18 (see FIG. 3B). Continued polishing then exposes the patterned top surface of the dielectric layer 14 (see FIG. 3C). Additional polishing can then be used to control the depth of the trenches that contain the conductive material 16.

In some implementations, a polishing system includes additional polishing stations. For example, a polishing system can include two or three polishing stations. For example, the polishing system can include a first polishing station with a first electromagnetic induction monitoring system and a second polishing station with a second electromagnetic induction current monitoring system.

For example, in operation, bulk polishing of the conductive layer on the substrate can be performed at the first polishing station, and polishing can be halted when a target thickness of the conductive layer remains on the substrate. The substrate is then transferred to the second polishing station, and the substrate can be polished until an underlying layer, e.g., a patterned dielectric layer.

Returning to FIG. 1, the polishing system includes an in-situ eddy current monitoring system 100 which can be coupled to or be considered to include a controller 90. The in-situ eddy current monitoring system 100 is configured to generate a signal that depends on a thickness of the conductive material 16, e.g., the metal, of the layer being polished.

In operation, the polishing system can use the in-situ eddy current monitoring system 100 to determine when the conductive layer has reached a target thickness, e.g., a target thickness for a metal layer overlying a dielectric layer, and then halt polishing. Alternatively or in addition, the polishing system can use the in-situ eddy current monitoring system 100 to determine differences in thickness of the conductive material 16 across the substrate 10, and use this information to adjust the pressure in one or more chambers 82 in the carrier head 80 during polishing in order to reduce polishing non-uniformity. During polishing, the measurements from the sensor 102 can be displayed on an output device to permit an operator of the polishing station to visually monitor the progress of the polishing operation, although this is not required.

The sensor 102 of the in-situ monitoring system 100 can be installed in a recess 26 in the platen 20. The sensor 102 can include a magnetic core 104 positioned at least partially in the recess 26, and at least one coil 106 wound around a portion of the core 104. Drive and sense circuitry 108 is electrically connected to the coil 106. The drive and sense circuitry 108 generates a signal that can be sent to the controller 90. The circuitry 108 can include a capacitor connected in parallel with the coil 106. Together the coil 106 and the capacitor can form an LC resonant tank. Although illustrated as outside the platen 24, some or all of the drive and sense circuitry 108 can be installed in the platen 24. A rotary coupler 29 can be used to electrically connect components in the rotatable platen 24, e.g., a sensor 102 of the eddy current monitoring system 100, to components outside the platen, e.g., drive and sense circuitry or the controller 90. Alternatively, the sensor 102 can be in wireless communication with the controller 90.

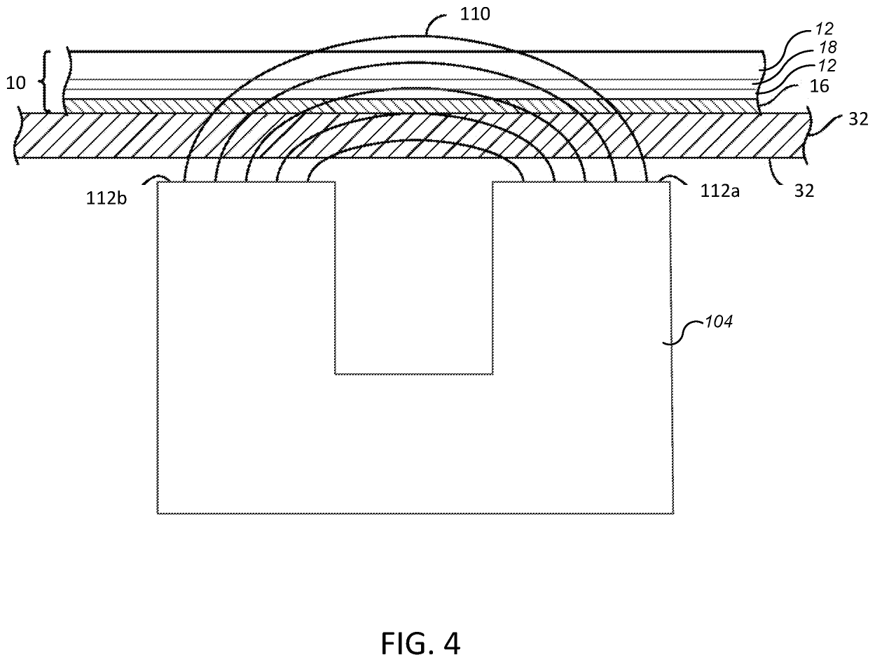

Referring to FIGS. 1 and 4, the drive and sense circuitry 108 applies an AC current to the coil 106, which generates a magnetic field 110 between two poles 112a and 112b of the core 104. In operation, when the substrate 10 intermittently overlies the sensor 102, a portion of the magnetic field 110 extends into the substrate 10.

If monitoring of the thickness of a conductive layer on the substrate is desired, then when the magnetic field 110 reaches the conductive layer 16, the magnetic field 110 can create an eddy-current in the conductive layer. This modifies the effective impedance of the LC circuit.

However, the magnetic field 110 can also penetrate into various conductive layers 18 “below” the layer being polished (above in view of FIG. 4) and into the semiconductor substrate 12. As such, the effective impedance of the LC circuit, and thus the signal from the drive and sense circuitry 108, can also depend on the conductivity of the underlying conductive layers and on the doping and resultant conductivity of the semiconductor substrate 12. Patterning of the layers is not shown in FIG. 4 for ease of illustration.

The drive and sense circuitry 108 can include a marginal oscillator coupled to a combined drive/sense coil 106, and the output signal can be a current required to maintain the peak to peak amplitude of the sinusoidal oscillation at a constant value, e.g., as described in U.S. Pat. No. 7,112,960. Other configurations are possible for the drive and sense circuitry 108. For example, separate drive and sense coils could be wound around the core. The drive and sense circuitry 108 can apply current at a fixed frequency, and the signal from the drive and sense circuitry 108 can be the phase shift of the current in the sense coil relative to the drive coil, or an amplitude of the sensed current, e.g., as described in U.S. Pat. No. 6,975,107.

Referring to FIG. 2, as the platen 24 rotates, the sensor 102 sweeps along a path 120 that passes below the substrate 10. By sampling the signal from the circuitry 108 at a particular frequency, the circuitry 108 generates measurements at a sequence of sampling zones 94 across the substrate 10. For each sweep, measurements at one or more of the sampling zones 94 can be selected or combined. Thus, over multiple sweeps, the selected or combined measurements provide a time-varying sequence of values.

The polishing station 20 can also include a position sensor 96, such as an optical interrupter, to sense when the sensor 102 is underneath the substrate 10 and when the sensor 102 is off the substrate. For example, the position sensor 96 can be mounted at a fixed location opposite the carrier head 70. A flag 98 can be attached to the periphery of the platen 24. The point of attachment and length of the flag 98 is selected so that it can signal the position sensor 96 when the sensor 102 sweeps underneath the substrate 10.

Alternately or in addition, the polishing station 20 can include an encoder to determine the angular position of the platen 24.

Returning to FIG. 1, a controller 90, e.g., a general purpose programmable digital computer, receives the signals from sensor 102 of the in-situ monitoring system 100. Since the sensor 102 sweeps beneath the substrate 10 with each rotation of the platen 24, information on the depth of the conductive layer, e.g., the bulk layer or conductive material in the trenches, is accumulated in-situ (once per platen rotation). The controller 90 can be programmed to sample signals from the in-situ monitoring system 100 when the substrate 10 generally overlies the sensor 102.

In addition, the controller 90 can be programmed to calculate the radial position of each measurement, and to sort the measurements into radial ranges, e.g., as discussed in U.S. Pat. No. 6,399,501.

Since the sensor 102 sweeps underneath the substrate 10 with each rotation of the platen 24, information on the conductive layer thickness is being accumulated in-situ and on a continuous real-time basis for each of multiple different radial zones on the substrate.

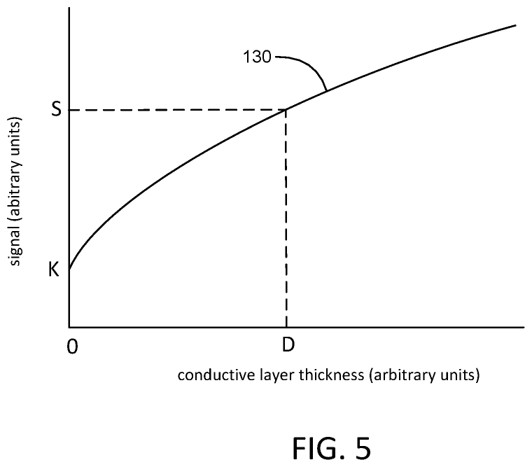

FIG. 5 shows a graph that illustrates a relationship curve 130, for a given resistivity, between the thickness of the conductive layer and the signal from the eddy current monitoring system 100. As shown, a given thickness D can be calculated from the signal S; K is a constant representing a value of the signal for zero conductive layer thickness.

The relationship curve 130 can be represented in the controller 90 by a function, e.g., a polynomial function, e.g., a second order function, a third order function, or a higher order function. Absent the doped semiconductor wafer, the correlation between the signal S and the thickness D can be represented by the equation:

$$S = {W}_{1} \cdot {D}^{2} + {W}_{2} \cdot D + {W}_{3} \qquad ( Equation 1 )$$

where W₁, W₂, and W₃ are real number coefficients. Thus, the controller can store the values of the coefficients of the function, e.g., W₁, W₂, and W₃, as well as the resistivity ρ₀ for which the relationship curve 410 applies. In addition, the relationship could be represented with a linear function, a Bezier curve, or a non-polynomial function, e.g., exponential or logarithmic.

Moreover, relationship curve or the thickness calculated for the layer can take into account the processing temperature, i.e., the temperature of the polishing pad, polishing liquid, substrate, or some combination thereof. For example, a corrected thickness value D′ can be calculated as follows:

$${D}^{′} = D * ( {ρ}_{T} / {ρ}_{0} )$$

$${ρ}_{T} = {ρ}_{X} [ 1 + α ( T - {T}_{ini} ) ]$$

where ρ_{X} is the resistivity of the conductive layer, and ρ₀ is the resistivity for which the relationship curve 130 is generated, Tᵢₙᵢ is the temperature for which the relationship curve 130 is generated, T is measured temperature for the process, e.g., from the temperature sensor 64, and α is a constant which can be derived empirically or from scientific textbooks.

Some variation in the signal intensity from the sensor 102 can be caused by the measurement region of the sensor 102 overlapping the substrate edge, rather than an intrinsic variation in the thickness or conductivity of the layer being monitored. Consequently, this distortion in the signal can cause errors in the calculating of a thickness value for the substrate, particularly near the substrate edge. To address this problem, the controller 90 can feed each thickness trace into a neural network that is configured to generate a modified thickness trace that compensates for compensate such signal distortions. Such a process is described in U.S. Patent Publication No. 2021-0379723. The resulting thickness measurements can be sorted in to the radial ranges.

As noted above, the signal generated by the eddy current sensor also includes the contribution from underlying conductive layers and the doped semiconductor wafer. Because the eddy currents excited in the doped semiconductor wafer and the conductive layer are independent and separated by insulating layers, the power dissipations into the doped silicon substrate and the insulated conductive film layer are additive and should generally follow the superposition principle of the linear systems.

Unfortunately, in many situations the doping of the semiconductor wafer is not tightly controlled, and thus is highly variable both across a wafer and on a wafer-to-wafer basis, even for wafers within a given production lot. On the other hand, in some situations the starting thickness of the conductive layer being polishing is known with high precision and reliability. For example, this can occur when the deposition process for forming the conductive is reliable and the thickness of a conductive layer on a calibration substrate or on a sample substrate from a production lot can be measured with other techniques, e.g., a four-point probe.

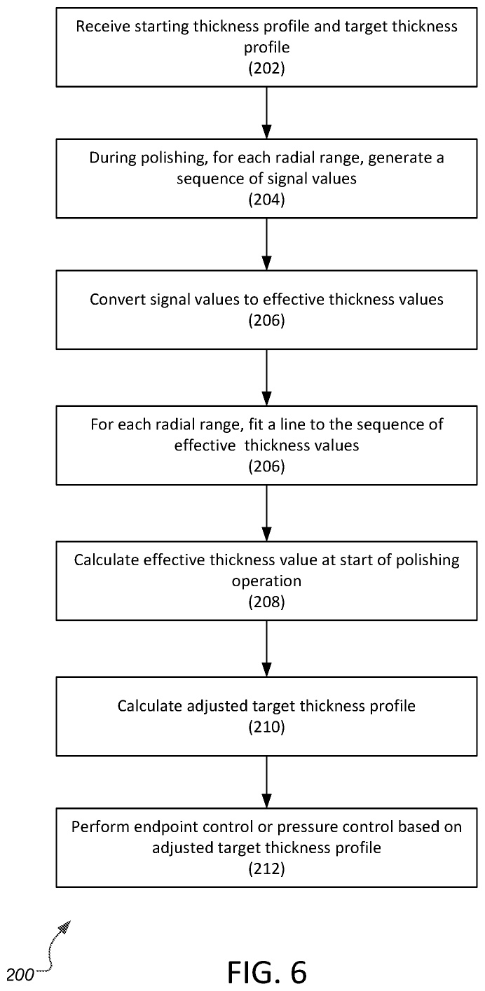

FIG. 6 illustrates a flow chart showing a process 200 for polishing a substrate and detecting an endpoint or adjusting a polishing parameter during the polishing operation.

The controller 90 can receive and store a starting film thickness profile and a target thickness profile (202). This starting thickness profile can be a set of starting thickness values representing the starting thickness, i.e., before polishing, of the conductive layer to be polished, at each of a plurality of radial zones. The number of radial zones, and thus the number of starting thickness values, can equal the number of independently controllable zones provided by the carrier head 140, e.g., three zones for the three concentric chambers 82a-82c shown in FIG. 1. These values can be obtained and entered by the fab facility operator. For example, a thickness of a conductive layer on a calibration substrate or on a sample substrate from a production lot can be measured, e.g., using a four-point probe technique, at each radial range. For N radial ranges, the starting thickness values can be represented as ST₁, ST₂, . . . . ST_{N}. Where a reference radial range and a dynamically controlled radial range are used, the target thickness values can be represented as ST_{R}, and ST_{D}.

Similarly, the target thickness profile can be a set of target thickness values representing the desired thickness to be achieved, i.e., after polishing, at each of the plurality of radial zones. And likewise, the number of target thickness values can equal the number of starting thickness values and equal the number of independently controllable zones provided by the carrier head 140. For N radial ranges, the target thickness values can be represented as TT₁, TT₂, . . . . TT_{N}. These values can be selected by the fab facility operator based on specifications for the integrated circuit being fabricated. Where a reference radial range and a dynamically controlled radial range are used, the target thickness values can be represented as TT_{R}, and TT_{D}.

Referring to FIGS. 2 and 6, with each sweep of the sensor 102 beneath the substrate 10, the eddy current monitoring system generates a series of measurements, in the form of raw signal values, corresponding to the different sampling zone 94. These signal values are sorted by the controller 90 into different radial ranges. These different radial ranges can match the radial ranges for the starting thickness values, i.e., in a one-to-one relationship.

For each radial range, the raw signal values from one or more of the sampling zones 94 within that radial range can be selected or combined to provide a measurement, i.e., a signal value, for that range. As a result, for each sweep, the eddy current monitoring system 100 generates a one or more signal values for each radial range. Thus, as polishing progress over time and multiple sweeps of the sensor 12 occur, the eddy current monitoring system 100 generates a sequence of signal values for each radial range (step 204).

Referring to FIGS. 2 and 5, each signal value(S) from the sequence is converted to an effective thickness value (D) (step 206), e.g., using the relationship curve 130, thereby generating a sequence of effective thickness values for each radial range. The term “effective thickness value” is used because the value is calculated as if the signal is entirely due to the conductivity of the layer being polished. But in fact the signal includes the contribution from the underlying layer and doped substrate, which can have different conductivities than the layer being polished but are incorporated into the measurement as an additional thickness of the material being polished.

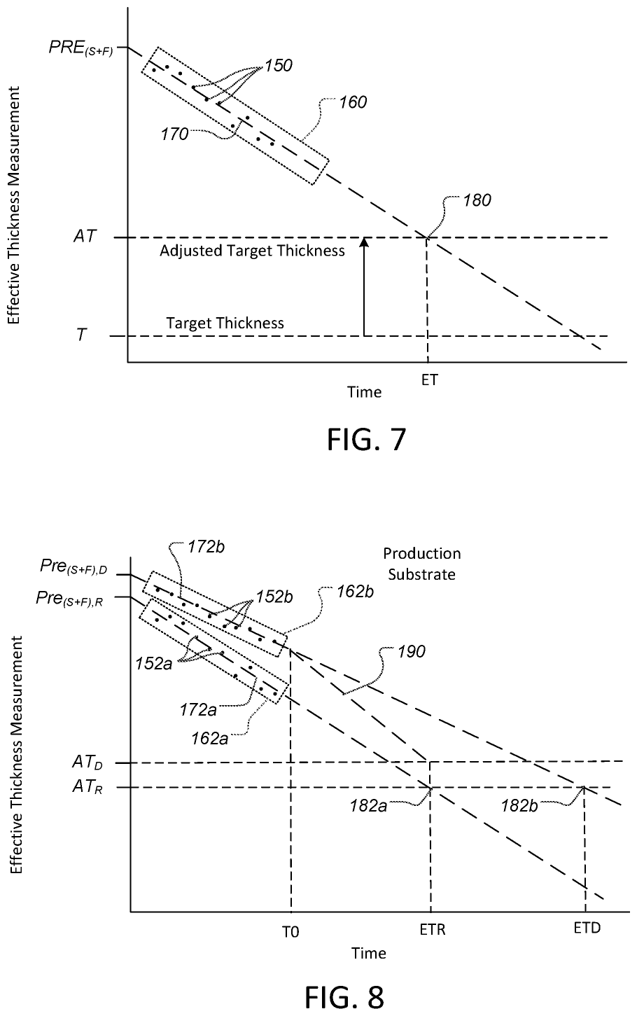

FIG. 7 illustrates a graph (shown for illustration of the process; no graph need be generated or displayed in operation) that shows a sequence 160 of effective thickness values 150 generated for a particular radial range, with one signal value 200 generated for each sweep of the sensor 102 below the substrate 10.

For each radial range, a polynomial function, e.g., a first-order function, i.e., a line 170, is to fit to the sequence 160 of effective thickness values 150 for that radial range (step 208). For example, the fitting can be performed using robust regression. In particular, the line 170 can be fit to effective thickness values accumulated after polishing commences but before the first parameter change, e.g., the first time the carrier head pressure or other variable is changed to improve the polishing uniformity. Effective thickness values from the initial one to three rotations of the platen can be excluded, as the polishing rate may be unstable during this period. And depending on when carrier head pressure starts to change, effective thickness values acquired after the pressure change should be excluded so that the slope of the line 170 thus represents a polishing rate for the associate radial range. Four to ten effective thickness values may be sufficient data for fitting of the line 170, although fitting of the line may continue as polishing progresses.

The effective thickness value at the start of polishing operation is calculated (step 208). For example, from the fitted polynomial function, the controller 90 extrapolates backwards to determine an effective starting thickness value (PRE) for the substrate at the start of polishing process. For N radial ranges, the effective starting thickness values can be represented as PRE_{(F+S),1}, PRE_{(F+S),2} . . . . PRE_{(F+S),N}. The subscript F+S indicates that the thickness value includes contributions of both the layer being polished and the underlying substrate. For a reference radial range, the effective starting thickness values can be represented as PRE_{(F+S),R}; for a dynamically controlled radial range, the effective starting thickness values can be represented as PRE_{(F+S),D}.

With the target thickness values, starting thickness values, and effective thickness values in hand, and adjusted target thickness value is calculated (step 210). In particular, an adjusted target thickness value (AT) can be calculated as

$$AT = {PRE}_{{( F + S )}^{-}} ( ST - TT ) * k$$

where k is a constant.

In some implementations, this calculation is performed only for one reference radial range from the set of radial ranges, e.g., AT_{R}=PRE_{(F+S),R}−(ST_{R}−TT_{R})*k. In some implementations, this calculation is performed for each radial range, e.g., AT₁=PRE_{(F+S),1}−(ST₁−TT₁)*k, AT₂=PRE_{(F+S),2}−(ST₂−TT₂)*k, etc. If the calculation is performed for each radial range, then the same value of k can be used for each range.

Without being limited to any particular theory, k may be either or both of 1) compensation for the effect of the non-linear relationship curve, and 2) the effect of cross-talk between the conductive layer being polished and the underlying layers that causes the measurement to not follow the superposition principle for linear systems. The constant k can be determined empirically, and can be in the range of 1.0 to 1.2. For example, for a highly doped P++ silicon wafer, k can be about 1.04.

The controller 90 can perform endpoint detection or profile control, i.e., calculation of adjustments for carrier head pressure, using a conventional algorithm but substituting the adjusted target thickness values for the target thickness values in the endpoint or profile control algorithm (step 212).

For example, still referring to FIG. 7, as polishing progresses, the controller 90 can extrapolate forward to determine a time at which the line 170 will equal (at 180) the adjusted target thickness value. This time provides the endpoint time (ET).

As another example, by substituting the adjusted target thickness values for the target thickness values in the profile control algorithm, the algorithm will drive the polishing process toward providing those adjusted target thickness values. For example, FIG. 8 illustrates a graph (again shown for illustration of the process; no graph need be generated or displayed in operation) that shows two sequences of thickness values generated for two different radial ranges. In this example, first effective thickness values 152a are obtained and a first line 172a is fit to the first effective thickness values 152a for a first radial range, and second effective thickness values 152b are obtained and a second line 172b is fit to the second effective thickness values 152b for a second radial range. Assuming the first radial range is used as the reference radial range, the endpoint time ET_{R} can be calculated as the time the first line 172a reaches the first adjusted target thickness value AT_{R} (at 182a). Assuming the second radial range is used as the dynamic range, an endpoint time ETD is calculated as the time the second line 172b reaches the first adjusted target thickness value AT_{D} (at 182b). The controller 90 can calculate a target polishing rate 190 to begin at adjustment time TO for the dynamic radial range such that the both the control radial range and the dynamic radial range reach their respective adjusted target thickness values AT_{R} and AT_{D} at substantially the same time. In order to achieve the target polishing rate 190, the controller 90 can calculate an adjustment for one or more polishing parameters, e.g., an adjustment for the pressure in a zone of the carrier head corresponding to the dynamic radial range. This calculation can be based on the Preston Equation. As a result, the resulting polishing profile should more closely match the target profile, even if the underlayer contribution to the eddy current signal is inconsistent on a wafer-to-wafer basis.

As an alternative to measuring the starting thickness value on the layer with a four-point probe, an effective starting thickness value could be determined for reach radial region using the in-situ monitoring system. Moreover, instead of using absolute values, thicknesses of some of the zones can be represented using offsets as compared to a reference zone. A process using both of these techniques is described below, but each could be used independently.

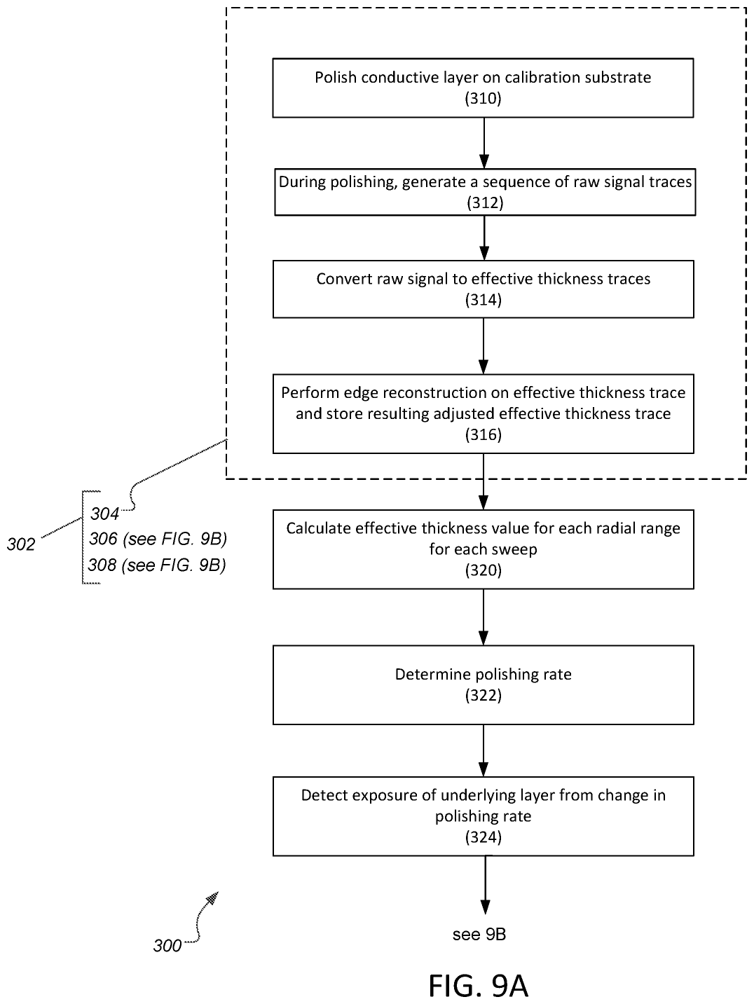

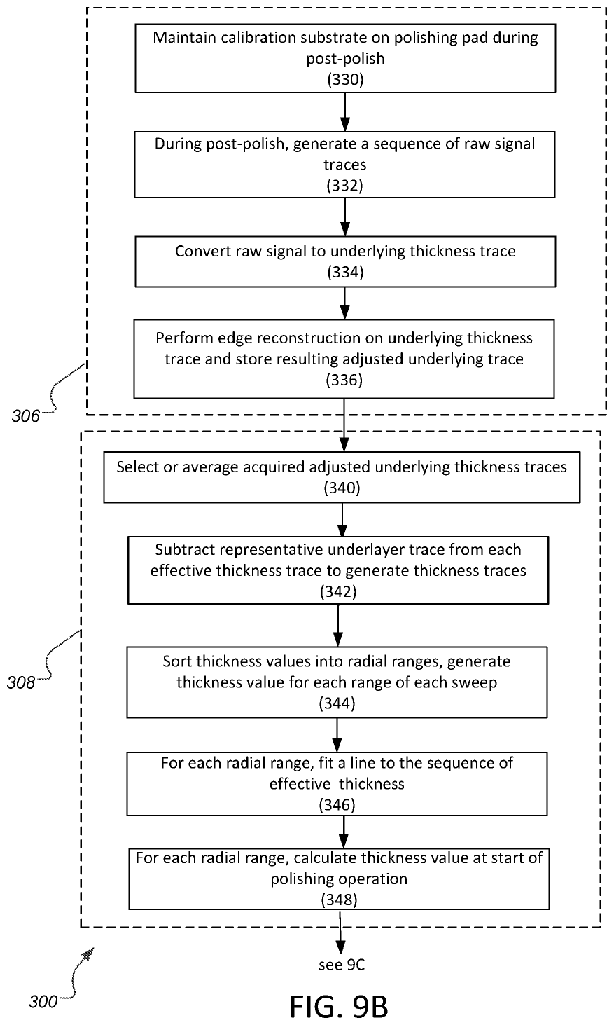

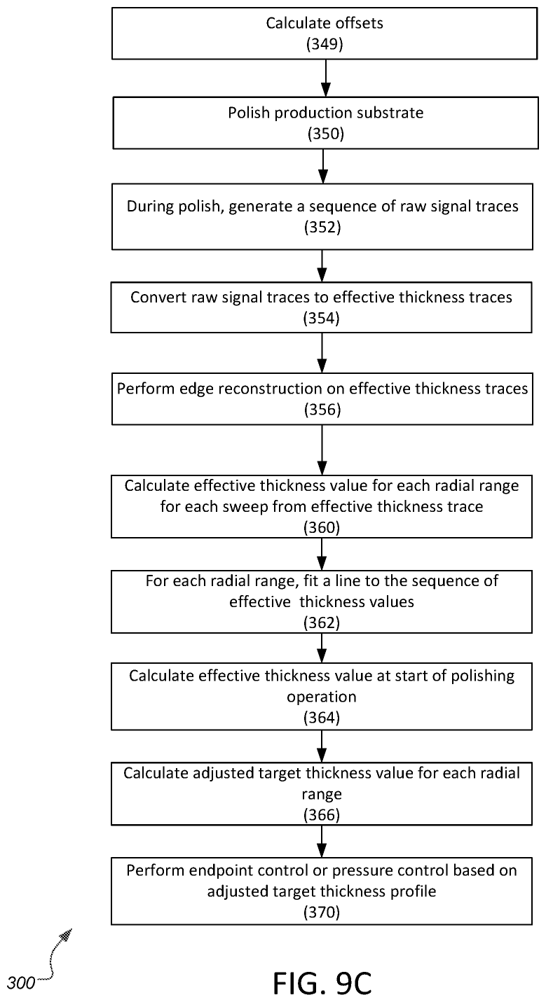

FIGS. 9A-9C illustrates a method 300 for performing endpoint and profile control in chemical mechanical polishing which includes a process 302 for determining starting thickness values for reach radial region using the in-situ monitoring system. This process includes generating thickness traces during bulk polishing of conductive layer on a calibration substrate (304), generating thickness traces once the conductive layer has been removed to expose an underlying layer (306), and processing the thickness traces to generate starting thickness values for each radial range (308). Each of these steps will be described in further detail below.

Initially, referring to FIG. 9A, a calibration substrate having the same layers and pattern as a production substrate is polished at a polishing station 20. During polishing of the outer conductive layer (step 310), the substrate is monitored with the in-situ eddy current monitoring system 160. Referring to FIGS. 2, 9A and 12, each sweep of the sensor 120 below the substrate 10 generates a raw signal trace (step 312). Each signal value in a raw signal trace can be converted to a thickness value (step 314), e.g., using the calibration relationship discussed above with reference to FIG. 5. This generates an effective thickness trace 300 for each sweep of the sensor 102 below the calibration substrate.

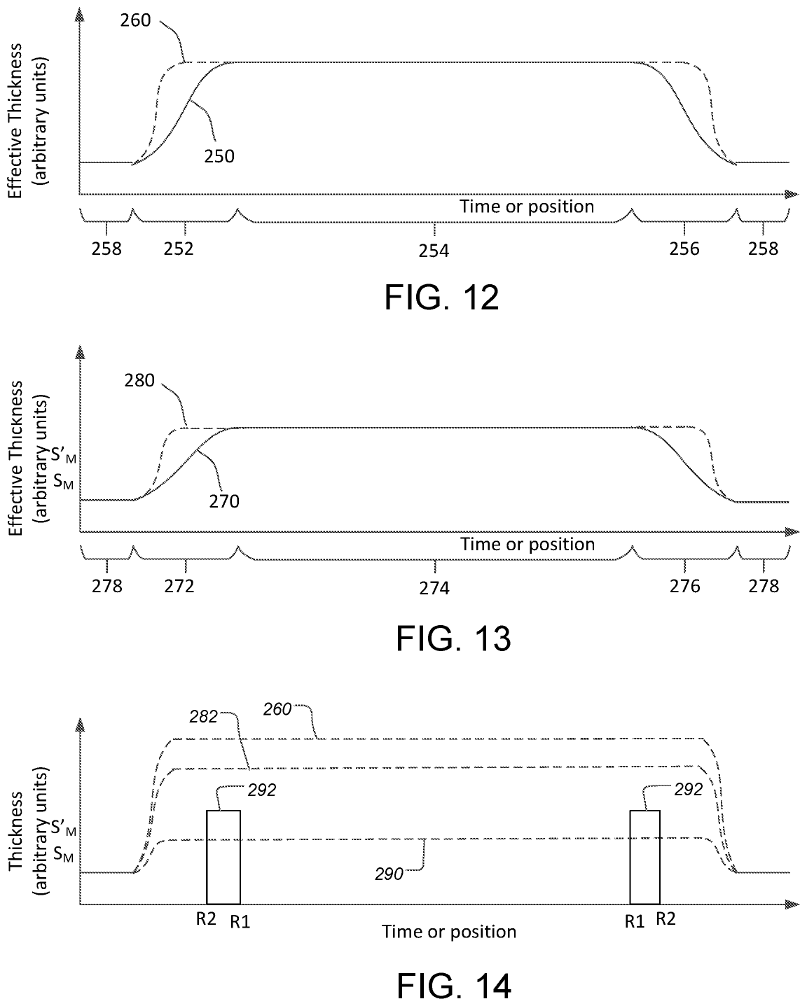

As shown in FIG. 12, the effective thickness trace 250 includes a first portion 252 that corresponds to locations in an edge region of the substrate 10 when the sensor crosses a leading edge of the substrate 10, a second portion 254 that corresponds to locations in a central region of the substrate 10, and a third portion 256 that corresponds to locations in edge region when the sensor 102 crosses a trailing edge of the substrate 10. The signal can also include portions 258 that correspond to off-substrate measurements, i.e., signals generated when the sensor head scans areas beyond the edge of the substrate 10.

Although the first and third portions 252, 256 are illustrated as smooth and the second portion 254 is illustrated as flat, this is for simplicity, and a real signal would include fluctuations due both to noise and to variations in the layer thickness. Moreover, although the effective thickness trace 250 is illustrated as continuous, in reality it is provided by a sequence of individual effective thickness values.

Continuing with FIGS. 9A and 12, as described above, thickness measurements at the substrate edge can be inaccurate. Therefore, an edge reconstruction technique can be performed on each effective thickness trace 250, thus generating a modified effective thickness trace 260 for each scan (step 316). In particular, each effective thickness trace 250 can be fed into a neural network that is configured to compensates for signal distortions at the substrate edge. Such a process is described in U.S. Patent Publication No. 2021-0379723. Each of the modified effective thickness traces 260 can be stored for subsequent processing.

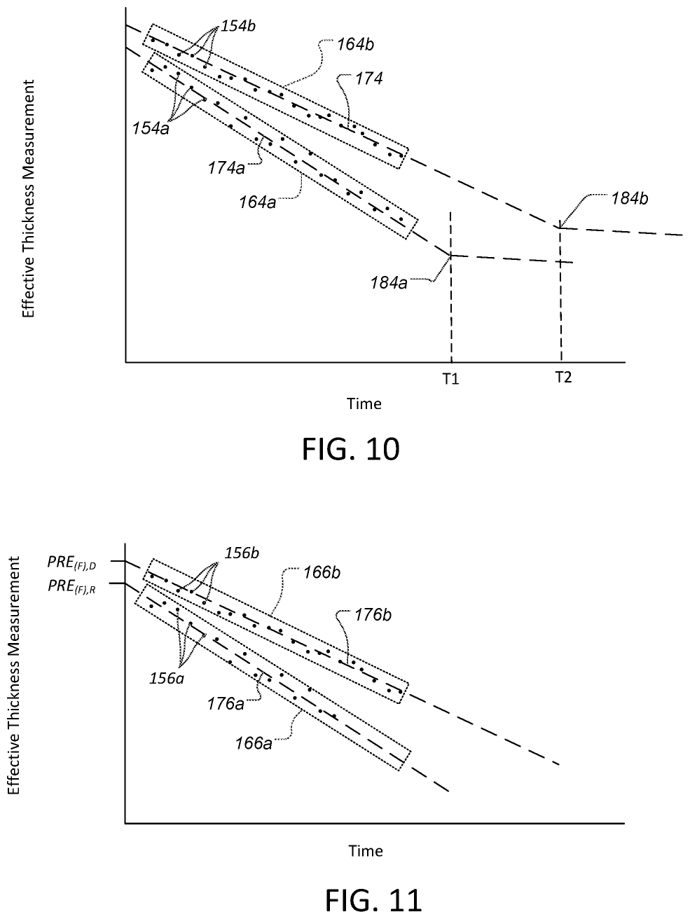

Referring to FIGS. 9A and 10, the thickness values from each modified effective thickness trace 260 can be sorted into radial ranges, and an effective thickness value can be calculated for each radial range for each sensor sweep (step 320). For example, one sequence 164a of effective thickness values 154a is generated for the reference radial range, and a sequence 164b of effective thickness values 154b is generated for each dynamic radial range (only two sequences are shown FIG. 10 for ease of illustration). The effective thickness value can be generated by averaging the effective thickness value from the trace 260 for the particular radial range.

The controller 90 can detect when the conductive layer has been polished away to expose an underlying layer. In this state, the top surface of the underlying layer is exposed, although there might be conductive material remaining in trenches to form conductive lines, vias, etc. In one implementation, the controller 90 or operator can detect a change in the slope (at 184) of a line fit to the sequence 164a of effective thickness values 154a for the reference zone. For example, the controller 90 can repeatedly fit a line to effective thickness values 154a from a running window of three to ten effective thickness values, and calculate a polishing rate from the slope of the line (step 322). If the slope of the line changes by more than a threshold value, the controller 90 can use this as an indication that the underlying layer has been exposed (step 324). In some implementations, a change in slope in just the reference radial range is sufficient to indicate exposure. In some implementations, a change in slope is required for the reference radial range and the dynamic radial ranges. In addition, other techniques can be used to find the time at which the underlying layer is exposed, e.g., a separate optical monitoring signal.

With the underlying layer exposed, referring to FIG. 9B, the calibration substrate can now be scanned during a “post-polish” process. In particular, the substrate is maintained on the polishing pad after the underlying layer is exposed (step 330), and the platen 24 continues to rotate to scan the sensor 102 below the substrate 10, thus generating a sequence of raw signal traces (step 332). To prevent removal of material in this post-polish process, the scanning of the calibration substrate can be conducted with the polishing pad surface flushed by deionized water (DIW) and/or with the chambers in the carrier head at low pressure, e.g., vented to atmosphere or less than 0.1 psi. Substantially no polishing can occur during this post-polish process, e.g., the polishing rate can be less than 5%, e.g., less than 1% of the polishing rate during the bulk polishing (in step 310).

Referring to FIGS. 9B and 13, each signal value in a raw signal trace can be converted to an underlying thickness value (step 334), e.g., using the relationship curve discussed above with reference to FIG. 5. For the post-polish process, this generates an underlying thickness trace 270 for each sweep of the sensor 102 below the calibration substrate.

As shown in FIG. 13, the underlying thickness trace 270 also includes a first portion 272 that corresponds to locations in an edge region of the substrate 10 when the sensor crosses a leading edge of the calibration substrate, a second portion 274 that corresponds to locations in a central region of the substrate 10, and a third portion 276 that corresponds to locations in edge region when the sensor 102 crosses a trailing edge of the substrate 10. The signal can also include portions 278 that correspond to off-substrate measurements, i.e., signals generated when the sensor head scans areas beyond the edge of the substrate 10.

Continuing with FIGS. 9B and 13, as described above, thickness measurements at the substrate edge can be inaccurate. Therefore, the edge reconstruction technique can also be performed on each underlying thickness trace 270, thus generating a modified underlying thickness trace 280 for each scan (step 336). In particular, each underlying thickness trace 270 can be fed into a neural network that is configured to compensates for signal distortions at the substrate edge. Such a process is described in U.S. Patent Publication No. 2021-0379723. Each of the modified underlying thickness traces 280 can be stored for subsequent processing.

With the adjusted effective thickness traces 260 acquired from bulk polishing of the conductive layer on the substrate (step 304) and the adjusted underlying thickness traces 280 acquired from the post-polish scanning of the substrate (step 306), starting thickness values for each radial range can now be determined (step 308).

In particular, referring to FIGS. 9B and 14, a representative underlying thickness trace 282 is generated (340) from the adjusted underlying thickness traces 280. For example, one of the adjusted underlying thickness traces can be selected as the representative underlying thickness trace. Alternatively, two more adjusted underlying thickness traces can be averaged to generate the representative underlying thickness trace. For example, an average underlying thickness trace DS(t) can be calculated as

$${\hat{D}}_{S} ( t ) = \frac{1}{N} {\sum }_{i = 1}^{N} {D}_{i} ( t )$$

where Dᵢ(t) represents the individual adjusted underlying thickness traces and N is the number of underlying thickness traces.

Next, continuing with FIGS. 9B and 14, the representative underlayer trace 282 is subtracted from each effective thickness trace 260 to generate a thickness trace 290 (step 342) for each scan of the of substrate acquired in step 304, i.e.,

$${D}_{F} ( t ) = {D}_{S + F} ( t ) - {\hat{D}}_{S} ( t )$$

This trace can be termed a “thickness trace” because by subtracting the underlayer contribution from the effective thickness value that included both the substrate and the film thickness, just the contribution from the film thickness should remain.

Referring to FIGS. 9B, 11, and 14 the thickness values from each thickness trace 290 can be sorted into radial ranges, and a thickness value can be calculated for each radial range for each sensor sweep (step 344). For example, thickness values within a particular radial range for a particular sweep. As a result, one sequence 166a of thickness values 156a is generated for the reference radial range, and a sequence 166b of thickness values 156b is generated for each dynamic radial range (only two sequences are shown FIG. 11 for ease of illustration). For example, a thickness value for a radial range R1 to R2 can be generated by averaging the thickness values from the corresponding portion 292 of the thickness trace 290.

For each radial range, a polynomial function, e.g., a first-order function, i.e., a line 176, is to fit to the sequence 166a, 166b of thickness values 156a, 156b for that radial range (step 346). For example, the fitting can be performed using robust regression. In particular, the line 176 can be fit to thickness values accumulated after polishing commences but before exposure of the underlying layer. Thickness values from the initial one to three rotations of the platen can be excluded, as the polishing rate may be unstable during this period. In some implementations, four to thirty thickness values are be sufficient data for fitting of the line 176.

The thickness value at the start of polishing operation is calculated for each radial range (step 348). For example, from the fitted polynomial function, the controller 90 extrapolates backwards to determine a starting thickness value (PRE) for the substrate at the start of the polishing process of the calibration substrate. For a reference radial range, the starting thickness values can be represented as PRE_{(F),R}; for a dynamically controlled radial range, the effective starting thickness values can be represented as PRE_{(F),D}. The subscript F indicates that the thickness value should represent substantially just the contribution of the conductively layer, i.e., not the underlying layers or substrate.

Turning to FIG. 9C, for some implementations, the starting thickness values for the dynamic radial ranges can be stored as offsets (349). For example an offset ΔPRE_{D} can be calculate for each dynamic radial range as

$$Δ {PRE}_{( F ) , D} = {PRE}_{( F ) , R} - {PRE}_{( F ) , D} .$$

The system should now be ready for polishing of a production substrate. As described above, target thickness values for the reference radial range and the dynamic radial range, TT_{R}, and TT_{D} are typically provided by the operator depending on the application and integrated circuit being fabricated on the production substrate. The target thickness values for the dynamic radial ranges can also be stored as offsets. For example an offset ΔTT_{D} can be calculate for each dynamic radial range as

$$Δ {TT}_{D} = {TT}_{R} - {TT}_{D} .$$

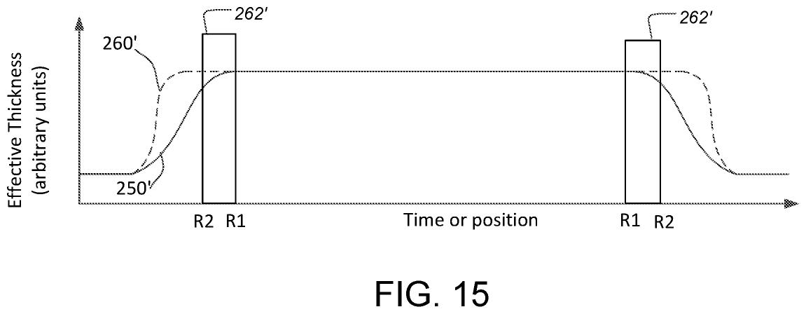

Continuing with FIGS. 9C and 15, the production substrate is polished at a polishing station 20 (350), and during polishing of the exposed conductive layer the substrate is monitored with the in-situ eddy current monitoring system 160. Each sweep of the sensor 102 below the substrate 10 generates a raw signal trace (step 352). Each signal value in a raw signal trace can be converted to an effective thickness value (step 354), e.g., using the relationship curve discussed above with reference to FIG. 5. This generates an effective thickness trace 250′ for each sweep of the sensor 102 below the production substrate. As with the calibration substrate, thickness measurements at the edge of the production substrate can be inaccurate. Therefore, an edge reconstruction technique can be performed on each effective thickness trace 250′, thus generating a modified effective thickness trace 260′ for each scan (step 356). In particular, each effective thickness trace 250′, can be fed into a neural network that is configured to compensates for signal distortions at the substrate edge. Such a process is described in U.S. Patent Publication No. 2021-0379723.

Continuing with FIG. 9C and returning to FIG. 8, the thickness values from each modified effective thickness trace 260′ can be sorted into radial ranges, and an effective thickness value can be calculated for each radial range for each sensor sweep (step 360). For example, one sequence 162a of effective thickness values 152a is generated for the reference radial range, and a sequence 162b of effective thickness values 152b is generated for each dynamic radial range (only two sequences are shown FIG. 8 for ease of illustration). Each effective thickness value 152a, 152b can be generated by averaging the effective thickness values from the corresponding portions of the corresponding effective thickness trace 260′. For example, an effective thickness value for a radial range R1 to R2 can be generated by averaging the effective thickness values from the corresponding portion 262 of the effective thickness trace 260′.

Once a sufficient number of effective thickness values are collected, a polynomial function, e.g., a first-order function, i.e., a line is to fit to each sequence of effective thickness values for that radial range (step 362). For example, a first line 172a is fit to the sequence 162a of thickness values 152a for the reference radial range. In addition, for each dynamic radial range, a line 172b is fit to the sequence 162b of effective thickness values 152b for that dynamic radial range. The fitting can be performed using robust regression. Effective thickness values from the initial one to three rotations of the platen can be excluded, as the polishing rate may be unstable during this period. And depending on when carrier head pressure starts to change, effective thickness values acquired after any pressure change should be excluded so that the slope of the lines 172a, 172b thus represent the polishing rates for the associate radial ranges before adjustment of the pressure. Four to ten effective thickness values may be sufficient data for fitting of the line 172a, 172b.

The effective thickness value at the start of polishing operation is calculated (step 364). For example, from the fitted polynomial function, the controller 90 extrapolates backwards to determine an effective starting thickness value (PRE) for the substrate at the start of polishing process. For a reference radial range, the effective starting thickness values can be represented as PRE_{(F+S),R}; for a dynamically controlled radial range, the effective starting thickness values can be represented as PRE_{(F+S),D}.

For some implementations, the effective starting thickness values for the dynamic radial ranges can be stored as offsets. For example an offset ΔPRE_{D} can be calculate for each dynamic radial range as

$$Δ {PRE}_{( F + S ) , D} = {PRE}_{( F + S ) , R} - {PRE}_{( F + S ) , D} .$$

With the target thickness values, starting thickness values, and effective thickness values in hand, an adjusted target thickness value is calculated for each radial range (step 366).

In particular, an adjusted target thickness value for the reference radial range (AT_{R}) can be calculated as

$${AT}_{R} = {PRE}_{( F + S ) R} - ( {PRE}_{( F ) , R} - {TT}_{R} ) * k$$

where k is the constant discussed above.

In addition, an adjusted target thickness value for each dynamic radial range (AT_{D}) can be calculated as

$${AT}_{D} = {AT}_{R} P + Δ {PRE}_{( F + S ) , D} - Δ {PRE}_{( F ) , D} + Δ {TT}_{R} .$$

The controller 90 can perform endpoint detection or profile control, i.e., calculation of adjustments for carrier head pressure, using a conventional algorithm but substituting the adjusted target thickness values for the target thickness values in the endpoint or profile control algorithm (step 370).

Continuing with FIG. 8, first effective thickness values 152a are obtained for the reference radial range and a first line 172a is fit to the first effective thickness values 152a, and second effective thickness values 152b are obtained for the dynamic radial range and a second line 172b is fit to the second effective thickness values 152b. The endpoint time ET_{R} is calculated as the time the first line 172a reaches the first adjusted target thickness value AT_{R} (at 182a). The second radial range is used as the dynamic range, and the endpoint time ETD is calculated as the time the second line 172b reaches the adjusted target thickness value AT_{D} for the second radial range (at 182b).

The controller 90 can calculate a target polishing rate 190 to begin at adjustment time TO for the dynamic radial range such that the both the control radial range and the dynamic radial range reach their respective adjusted target thickness values AT_{R} and AT_{D} at substantially the same time. In order to achieve the target polishing rate 190, the controller 90 can calculate an adjustment for one or more polishing parameters, e.g., an adjustment for the pressure in a zone of the carrier head corresponding to the dynamic radial range. This calculation can be based on the Preston Equation. As a result, the resulting polishing profile should more closely match the target profile, even if the underlayer contribution to the eddy current signal is inconsistent on a wafer-to-wafer basis.

The above described polishing apparatus and methods can be applied in a variety of polishing systems. Either the polishing pad, or the carrier heads, or both can move to provide relative motion between the polishing surface and the substrate. For example, the platen may orbit rather than rotate. The polishing pad can be a circular (or some other shape) pad secured to the platen. Some aspects of the endpoint detection system may be applicable to linear polishing systems, e.g., where the polishing pad is a continuous or a reel-to-reel belt that moves linearly. The polishing layer can be a standard (for example, polyurethane with or without fillers) polishing material, a soft material, or a fixed-abrasive material. Terms of relative positioning are used to refer to relative positioning within the system or substrate; it should be understood that the polishing surface and substrate can be held in a vertical orientation or some other orientation during the polishing operation.

Functional operations of the controller 90 can be implemented using one or more computer program products, i.e., one or more computer programs tangibly embodied in a non-transitory computer readable storage media, for execution by, or to control the operation of, data processing apparatus, e.g., a programmable processor, a computer, or multiple processors or computers.

A number of embodiments of the invention have been described. Nevertheless, it will be understood that various modifications may be made without departing from the spirit and scope of the invention. Accordingly, other embodiments are within the scope of the following claims.

What is claimed is:

1. A method of determining a starting thickness profile for a layer on a substrate, the method comprising:
polishing a conductive outer layer on a calibration substrate;
monitoring the calibration substrate during the polishing by repeatedly sweeping a sensor of an in-situ monitoring system across the calibration substrate so as to generate a sequence of first traces with each first trace of the sequence of first traces corresponding to a sweep by the sensor and each first trace including a sequence of effective thickness values that depend on a thickness of the conductive outer layer and on thickness and/or conductivity of one or more underlying layers below the outer layer;
detecting exposure of the one or more underlying layers below the outer layer;
following exposure of the one or more underlying layers, continuing to monitor the calibration substrate by sweeping the sensor of the in-situ monitoring system across the calibration substrate and generating a second trace that includes a sequence of underlying thickness values that depend on the thickness and/or conductivity of the one or more underlying layers;
for each respective first trace from the sequence of first traces, subtracting the second trace from the first trace to generate a modified first trace, thereby generating a sequence of modified traces;
for each respective zone of a plurality of zones on the substrate and each respective modified trace from the sequence of modified traces, converting a portion of the sequence of signal values from the respective zone for the respective modified trace into a thickness value for the respective zone, thereby providing a plurality of sequences of thickness values with each respective sequence of the plurality of sequences corresponding to a respective zone;
for each respective zone of the plurality of zones, fitting a function to the sequence of thickness values for the respective zone, thereby providing a plurality of fit functions with each respective fit function of the plurality of fit functions corresponding to a respective zone; and
determining a starting thickness profile for the conductive layer at a start of polishing using the plurality of fit functions.

2. The method of claim 1, comprising conducting the monitoring of the calibration substrate following exposure of the one or more underlying layers with substantially no polishing occurring.

3. The method of claim 2, comprising flushing a polishing surface of a polishing pad used for the polishing with a cleaning liquid to remove slurry from the polishing surface following exposure of the one or more underlying layers.

4. The method of claim 2, comprising reducing pressure in a chamber in the carrier head holding the calibration substrate to reduce pressure of the calibration substrate a polishing pad following exposure of the one or more underlying layers.

5. The method of claim 1, wherein the in-situ monitoring system comprises an eddy current monitoring system.

6. The method of claim 1, wherein the function is a linear function.

7. The method of claim 6, wherein determining the starting thickness profile comprises, for each respective zone of the plurality of zones, extrapolating the fit function for the respective zone backward to a starting time for the polishing.

8. The method of claim 1, wherein monitoring the calibration substrate during the polishing includes generating a sequence of raw signal traces with each raw signal trace of the sequence of raw signal traces corresponding to a sweep by the sensor and each raw signal trace including a sequence of raw signal values that depend on the thickness of the conductive outer layer and on the thickness and/or conductivity of the one or more underlying layers below the outer layer.

9. The method of claim 8, comprising converting the sequence of raw signal values to a sequence of effective thickness values.

10. The method of claim 9, wherein the sequence of raw signal values is converted to the sequence of effective thickness values using a signal-to-thickness relationship curve.

11. The method of claim 9, wherein converting the sequence of raw signal values to the sequence of effective thickness values includes converting the sequence of raw signal values to a sequence of preliminary effective thickness values, thereby generating a sequence of preliminary effective thickness traces.

12. The method of claim 11, comprising, for each respective preliminary effective thickness trace from the sequence of preliminary effective thickness traces, performing edge reconstruction on the respective preliminary thickness trace to generate the effective thickness trace.

13. The method of claim 1, comprising continuing to monitor the calibration substrate by repeatedly sweeping the sensor of the in-situ monitoring system across the calibration substrate so as to generate a sequence of underlying thickness traces.

14. The method of claim 13, comprising averaging two or more underlying thickness traces to generate the second trace.

15. The method of claim 13, wherein monitoring the calibration substrate after exposure of the one or more underlying layers includes generating a sequence of raw signal traces with each raw signal trace of the sequence of raw signal traces corresponding to a sweep by the sensor and each raw signal trace including a sequence of raw signal values that depend on the thickness and/or conductivity of the one or more underlying layers.

16. The method of claim 15, comprising converting the sequence of raw signal values to a sequence of underlying thickness values.

17. The method of claim 16, wherein the sequence of raw signal values is converted to the sequence of underlying thickness values using a signal-to-thickness relationship curve.

18. The method of claim 16, wherein converting the sequence of raw signal values to the sequence of underlying thickness values includes converting the sequence of raw signal values to a sequence of preliminary underlying thickness values, thereby generating a sequence of preliminary underlying thickness traces.

19. The method of claim 18, comprising, for each respective preliminary underlying thickness trace from the sequence of preliminary underlying thickness traces, performing edge reconstruction on the respective preliminary underlying thickness trace to generate the underlying thickness trace.

20. The method of claim 1, comprising:
for at least one zone of the plurality of zones on the substrate and each first trace from the sequence of first traces, converting a portion of the sequence of signal values from the zone for the respective first trace into an effective thickness value for the zone, thereby providing a sequences of effective thickness values for the zone, and
repeatedly fitting a second linear function to a running window of effective thickness values from the sequence of effective thickness values for the zone, thereby generating a sequence of fit second linear functions.

21. The method of claim 20, wherein detecting exposure of the one or more underlying layers includes detecting a change in slopes of the sequence of fit second linear functions.
